(19) United States
(12) Patent Application Publication
(10) Pub. No.: US 2026/0236721 A1
(43) Pub. Date: Aug. 13, 2026

(54) HIGH-SPEED SELECTIVE CARRY PROPAGATE ADDER

(71) Applicant: INDIAN INSTITUTE OF TECHNOLOGY MADRAS (IIT MADRAS), Tamil Nadu (IN)

(72) Inventors: Mohit SHARMA, Tamil Nadu (IN); Janakiraman VIRARAGHAVAN, Tamil Nadu (IN)

(73) Assignee: INDIAN INSTITUTE OF TECHNOLOGY MADRAS (IIT MADRAS), Tamil Nadu (IN)

(21) Appl. No.: 19/469,694

(22) PCT Filed: Mar. 28, 2024
(86) PCT No.: PCT/IN2024/050333

§ 371 Date: Sep. 26, 2025

(30) Foreign Application Priority Data
Mar. 31, 2023 (IN) 202341024699

(51) Int. Cl. G06G 7/14

(52) U.S. Cl. CPC G06G 7/14

(57) ABSTRACT

A high-speed selective carry propagate adder circuit includes a full adder with selective carry propagates in the critical path rather than the traditional way of carry propagation method, which limits the operating speed. Instead of propagating carry and using it for sum computation, propagating selective carry is in the critical path and used for sum computation. As a result, fewer transistors are needed in a full adder cell, which leads to faster performance and less power consumption due to reduced parasitic resistance and capacitance. In addition, the disclosed circuit design reduces the transistor count required for a one-bit full adder cell to 14 transistors in static CMOS logic, 10 transistors in transmission gate and 8 transistors in pass transistor logic style. Furthermore, the disclosed adder circuit offers a versatile and efficient solution for multi-bit adders in a variety of logic styles, with potential applications in various fields.

### CROSS-REFERENCE TO RELATED APPLICATIONS

This application is a U.S. National Stage Application under 35 U.S.C. § 371 of International Patent Application No. PCT/IN2024/050333, filed Mar. 28, 2024, which claims priority to Indian Patent Application No. 202341024699, filed Mar. 31, 2023, the contents of which are hereby incorporated by reference in their respective entireties.

### FIELD OF INVENTION

The present invention generally relates to the addition of two N-bit binary numbers. More particularly, the present invention relates to high-speed selective carry propagate adders.

### BACKGROUND OF THE INVENTION

One of the most fundamental and crucial arithmetic functions in modern digital systems, such as microprocessors, image and video processing, and digital signal processors (DSP), is the addition of two N-bit binary numbers.

Binary addition, performed using a full adder, is a fundamental operation in digital systems, and full adders are essential building blocks in arithmetic computations, such as subtraction, multiplication, and division. Along with central processing units (CPUs), full adders are essential building blocks of the multiply-accumulate (MAC) unit, commonly used in digital signal processing, neural networks, and in-memory computing applications.

The efficiency and speed of full adders directly impact the overall performance of digital systems. Thus, the performance of a digital computing system relies heavily on the speed at which adders can process data, as it determines the minimum clock cycle time.

This speed improvement benefits applications such as real-time processing, data-intensive computations, and high-performance computing. Additionally, faster binary operations contribute to energy efficiency by reducing computation time, resulting in lower energy consumption and extended battery life for portable devices.

While there have been advancements in adder architecture at the system level, such as the carry skip, carry save, and carry look ahead adders, the traditional mirror adder remains the most popular choice for full adder standard cells.

Traditional binary addition circuits, such as the mirror adder, inherits the advantages of static CMOS logic, such as rail-to-rail swing and high noise immunity. Alternate full adder circuits have been proposed in different logic styles.

However, the different logic styles bring their own set of advantages and disadvantages, impacting their applicability. The delay of a ripple adder employing any of these logic styles is limited by the method of carry propagation, which falls within the critical path. Such full adder circuits are referred to as traditional full adder circuits (TFAC). They have limitations such as long carry propagation delays, a high transistor count, high energy consumption, and limited flexibility.

Traditional full adder designs aim for a compact and efficient implementation of the Boolean functions. Numerous full adder designs in the categories of static CMOS, dynamic CMOS, pseudo-NMOS, transmission gates, and pass transistor logic have been presented in the prior arts. However, one drawback of such full adder designs is that they are specific to one particular logic style and cannot be implemented efficiently in other logic styles.

The mirror design full adder (MDFA), also known as mirror adder, is the most widely used conventional adder circuit in static CMOS logic. As shown in FIG. 1, the PMOS stack is an exact mirror of the NMOS stack in the mirror design full adder, but it requires as many as 24 transistors. One main disadvantage of such a design is that the higher number of transistors increases the parasitic resistance and capacitance, which in turn degrades signal integrity and contributes to slower operation speeds. Additional disadvantages include higher energy consumption, limiting the suitability of these circuits for energy-efficient computing systems.

An alternate design for a full adder, which requires only 18 transistors, can be realized through a two-stage computation approach known as Full Adder using Generate and Propagate (FAGP), as shown in FIG. 2. The speed of the adder circuit depends on both transistor count and transistor size, as these two factors determine the input capacitance. Despite the reduction in transistor count, the performance remains inferior to that of MDFA because of the slower carry propagation mechanism caused by the larger sizes of PMOS stacks used in sum computation. Furthermore, the primary reason for facing disadvantages with the Full Adder using Generate and Propagate (FAGP) design is that the sum is calculated using Gᵢ and Pᵢ, which are redundant boolean variables. A full adder cannot generate carry (Gᵢ) and propagate carry (Pᵢ) at the same time.

### OBJECTS OF THE INVENTION

An object of the invention is to provide a high-speed selective carry propagate adder circuit, offering faster performance, improved overall efficiency, and adaptability to various logic styles.

Another object of the invention is to provide a circuit that is capable to reduce the number of transistors required for a full adder cell, hence minimizing the propagation delay in the critical path.

Another object of the present invention is to provide a circuit that is compatible with other logic designs such as static CMOS, dynamic logic, transmission gate, pass transistor, making the design versatile and suitable for a wide range of applications.

Another object of the present invention is to provide a circuit that is capable of adding multi-bits efficiently without signal degradation in the critical path, resulting in improved robustness and higher operating speed.

Another object of the present invention is to provide a circuit that is capable of reducing the parasitic resistors and capacitors in the circuit, resulting in improved performance and higher operating speed.

Yet another object of the present invention is to provide a circuit that is capable of improving the logical effort of the full adder design, thereby resulting in improved operation speed in the circuit.

### SUMMARY OF THE INVENTION

The summary is provided to introduce aspects related to a full adder circuit comprising implementations in CMOS logic, transmission logic, pass transistor logic, etc. This summary is not intended to identify essential features of the claimed subject matter nor is it intended for use in determining or limiting the scope of the claimed subject matter.

In a preferred embodiment, the present invention provides a selective carry full adder circuit in static CMOS logic, comprising: first (V₁) and second (V₂) power source terminals across which is applied an operation voltage; a selective carry out generating circuit configured to receive a first input signal, a second input signal and a third input signal and generate a first output signal; a sum bit generating circuit, coupled to the selective carry out generating circuit, configured to receive the output signal from the selective carry out generating circuit, the first input signal, the second input signal and the third input signal and generate a second output signal; wherein the selective carry out generating circuit comprises a first pull up network and a first pull down network wherein the first pull down network comprises two NMOS transistors in parallel configured to receive a selective carry in (Mᵢ) and a generate from the previous adder stage (Gᵢ₋₁) and an NMOS transistor connected in series to the two transistors configured to receive a propagate carry signal (Pᵢ) and a ground voltage supply, and wherein the first pull up network is a complimentary logic of the first pull down network, and wherein the first output signal generated is a selective carry out signal (M̅ᵢ̅₊̅₁̅), wherein the sum bit generating circuit comprises a second pull up network and a second pull down network wherein the second pull down network comprises three NMOS transistors in parallel configured to receive a selective carry in (Mᵢ), a generate carry from the previous adder stage (Gᵢ₋₁) and a propagate carry signal (Pᵢ), and an NMOS transistor connected in series to the three transistors configured to receive the selective carry out signal (Mᵢ₊₁) from the selective carry generating circuit and a ground voltage supply, wherein the second pull up network is a complimentary logic of the second pull down network, and wherein the second output signal generated is a sum (S̅ᵢ̅) of the inputs.

In another preferred embodiment, the present invention provides a selective carry propagate full adder circuit in transmission gate logic, comprising: a selective carry out generator circuit; and a sum generator circuit; wherein the carry out generator circuit comprises: a selective carry input (M̅ᵢ̅) which passes through a first NMOS transistor with a generate input (G̅ᵢ̅₋̅₁̅) from the previous adder stage and generates a first non-inverted output, the first output passes through a first NOT gate (U1) and generates a second inverted output, the second output passes through a second NMOS transistor with a propagate carry input (Pᵢ) and generates a third output, the third output passes through a second NOT gate (U2) to provide a selective carry output (M̅ᵢ̅₊̅₁̅) and wherein the sum generator circuit comprises three inputs: comprising a carry propagate signal input (Pᵢ), the first non-inverted output from the selective carry out generator circuit and the second output from the selective carry out generator circuit into an inverter and a transmission gate to generate a sum (Sᵢ).

In another preferred embodiment, the present invention provides a selective carry propagate full adder circuit in pass transistor logic, comprising: a selective carry out generator circuit; and a sum generator circuit; wherein the carry out generator circuit comprises: a selective carry input (M̅ᵢ̅) which passes through a first NMOS transistor with a generate input (G̅ᵢ̅₋̅₁̅) from the previous adder stage and generates a first non-inverted output, the first output passes through a first NOT gate (U1) and generates a second inverted output, the second output passes through a second NMOS transistor with a propagate carry input (Pᵢ) and generates a third output, the third output passes through a second NOT gate (U2) to provide a selective carry output (M̅ᵢ̅₊̅₁̅), and wherein the sum generator circuit comprises three inputs: comprising a carry propagate signal input (Pᵢ) at the gate of a NMOS and PMOS pass transistor, the first non-inverted output and the second inverted output from the selective carry out generator circuit into a pass transistor to generate a sum (Sᵢ).

In another preferred embodiment, the present invention provides a method of adding three bits using a selective carry look ahead full adder circuit comprising: performing (901) a first NAND operation for first and second input terminals adapted to receive a first Carry in (C₀) and a first propagate (P₀) and producing a first output as inverted selective carry in signal (M̅₁̅); performing (902) a first AND operation for first and second input terminals adapted to receive the first output inverted selective carry in (M̅₁̅) and a first inverted generate carry (G₀) and produce an output which provides a first input signal to a first OR operation; performing (903) a first OR operation for first and second input terminals adapted to receive an output from the first AND operation and an inverted second propagate (P̅₁̅) to produce a second output as inverted selective carry in signal (M̅₂̅); performing (904) a second AND operation for first, second and third input terminals adapted to receive the first output inverted selective carry in (M̅₁̅), the inverted first generate carry (G̅₀̅) and an inverted second generate carry (G̅₁̅) and produce an output which provides a first input signal to a second OR operation; performing (905) a third AND operation for first and second input terminals adapted to receive the inverted second propagate (P̅₁̅) and inverted second generate carry (G̅₁̅) and produce an output which provides a second input signal to a second OR operation; performing (906) a second OR operation for first, second and third input terminals adapted to receive an output from the second AND operation, output from the third AND operation and an inverted third propagate (P̅₂̅) and produce a third output as inverted selective carry in signal (M̅₃̅); performing (907) a fourth AND operation for first, second, third and fourth input terminals adapted to receive the output (M̅₁̅) from the first NAND operation, the inverted first generate carry (G̅₀̅), the inverted second generate carry (G̅₁̅) and an inverted third generate carry (G̅₂̅) to produce an output which provides a first input signal to a third OR operation; performing (908) a fifth AND operation for first, second and third input terminals adapted to receive the inverted second propagate (P̅₁̅), the inverted second generate carry (G̅₁̅) and an inverted third generate carry (G̅₂̅) to produce an output which provides a second input signal to a third OR operation; performing (909) a sixth AND operation for first and second input terminals adapted to receive the third inverted propagate (P̅₂̅) and the inverted third generate carry (G̅₂̅) to produce an output which provides a third input signal to a third OR operation; performing (910) a third OR operation for first, second, third and fourth input terminals adapted to receive an output from the fourth AND operation, output from the fifth AND operation, output from the sixth AND operation and a fourth inverted propagate (P̅₃̅) and produce a fourth output as inverted selective carry in signal (M̅₄̅); and performing (911) a second NAND operation for first and second input terminals adapted to receive output from the third OR operation and a fourth inverted generate carry signal (G̅₃̅) and produce a carry out signal (C₄).

Other aspects and advantages of the invention will become apparent from the following description, taken in conjunction with the accompanying drawings, illustrating by way of example the principles of the invention.

### BRIEF DESCRIPTION OF THE DRAWINGS

The accompanying drawings constitute a part of the description and are used to provide further understanding of the present invention. Such accompanying drawings illustrate the embodiments of the present invention which are used to describe the principles of the present invention. The embodiments are illustrated by way of example and not by way of limitation in the figures of the accompanying drawings in which like references indicate similar elements. It should be noted that references to “an” or “one” embodiment in this invention are not necessarily made to the same embodiment, and they mean at least one. In the accompanying drawings:

FIG. 1 is a schematic diagram illustrating a prior art, Mirror Design Full Adder (MDFA) cell.

FIG. 2 is a schematic diagram illustrating a prior art, Full Adder using Generate and Propagate (FAGP).

FIG. 3A is a block diagram illustrating a High-speed Selective Carry Propagate Full Adder (SCPFA).

FIG. 3B is a schematic diagram illustrating a High-speed Selective Carry Propagate Full Adder (FA Even Block).

FIG. 4 is a schematic diagram illustrating a Multi-bit Adder/Subtractor using Selective Carry Propagate Adder.

FIG. 5 is a schematic diagram illustrating a High-speed Selective Carry Propagate Full Adder (FA_ODD Block).

FIG. 6 is schematic diagram illustrating a High-Speed Selective Carry Propagate Adder (Transmission gate logic style).

FIG. 7 is a schematic diagram illustrating a High-Speed Selective Carry Propagate Adder (Pass transistor logic style).

FIG. 8 is a schematic diagram illustrating a prior art of Carry Look Ahead Adder.

FIG. 9A is schematic diagram of Selective Carry Look Ahead Adder.

FIG. 9B illustrates a method of adding two bits in a Selective Carry Look Ahead Adder.

A more complete understanding of the present invention and its embodiments thereof may be acquired by referring to the following description and the accompanying drawings.

### DETAILED DESCRIPTION OF THE INVENTION

The detailed description set forth below in connection with the appended drawings is intended as a description of various embodiments of the present invention and is not intended to represent the only embodiments in which the present invention may be practiced. Each embodiment described in this invention is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

Approximating language, as used herein throughout the specification and claims, may be applied to modify any quantitative representation that could permissibly vary without resulting in a change in the basic function to which it is related. Accordingly, a value modified by a term or terms, such as “less than,” “approximately”, etc. is not limited to the precise value specified. In some instances, the approximating language may correspond to the precision of an instrument for measuring the value.

The present invention proposes a high-speed selective carry full adder circuit to improve the performance of digital systems such as microprocessors and digital signal processors. The present invention proposes using selective carry propagation in the critical path instead of using the traditional carry propagation method to improve performance, energy consumption, and adaptability to various logic designs. By propagating selective carry and using it for sum computation the transistor count is reduced, making the system faster and more energy efficient. The proposed circuit is versatile and its adaptability to different logic styles makes it suitable for a wide range of applications.

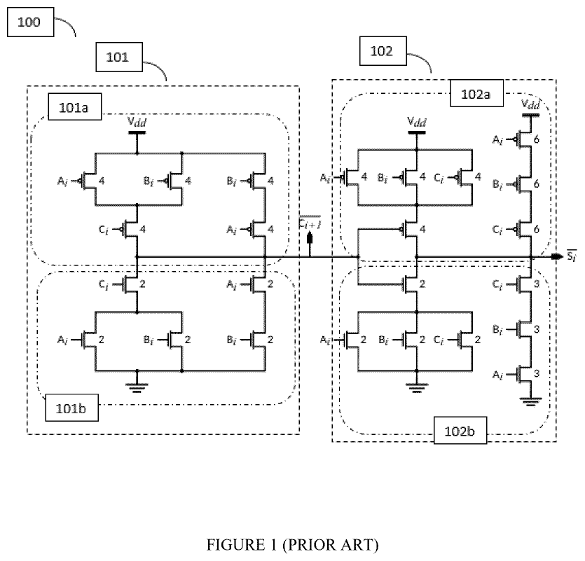

FIG. 1 illustrates a traditional full adder circuit (100) which comprises a carry-out generating circuit (101) and a sum generating circuit (102) according to a prior art. The carry-out generating circuit is configured to generate a first output signal (C̅ᵢ̅₊̅₁̅) based on a first input signal (Aᵢ), a second input signal (Bᵢ) and a third input signal (Cᵢ).

The sum bit generating circuit (102) is coupled to the carry out generating circuit (101) and configured to receive the first output from the carry out generating circuit (C̅ᵢ̅₊̅₁̅) and generate a second output signal Sum (Sᵢ) based on the first input signal (Aᵢ), Second input signal (Bᵢ), a third input signal (Cᵢ) and the first output signal (C̅ᵢ̅₊̅₁̅) wherein the second output signal is the output Sum bit of the full adder circuit.

The circuit as described in FIG. 1 is a mirror design full adder (MDFA) circuit (100), which comprises a plurality of pull-up networks and pull-down networks wherein each pair of pull-up and pull-down network are symmetric in structure.

The carry out generating circuit (101) may comprise sub-units in the form of a first pull up network sub unit (101a) and a first pull-down network sub unit (101b). The pull up sub unit (101a) is configured to receive inputs Aᵢ and Bᵢ in parallel PMOS transistors and an input Cᵢ in a PMOS transistor in series with the inputs Aᵢ and Bᵢ. There are two further PMOS transistors for inputs Aᵢ and Bᵢ in series and positioned parallelly to the remaining inputs. The pull-down sub unit (101b) is complimentary (also mirror) to the pull-up sub unit and both the sub units generate an output signal (C̅ᵢ̅₊̅₁̅) which becomes an input for the sum bit generating circuit (102).

The sum bit generating circuit (102) may comprise sub units in the form of a second pull-up network sub unit (102a) and a second pull-down network sub unit (102b). The pull up sub unit (102a) is configured to receive inputs Aᵢ, Bᵢ and Cᵢ in parallel PMOS transistors in series with a PMOS transistor receiving input signal (C̅ᵢ̅₊̅₁̅). There are three further PMOS transistors for inputs Aᵢ, Bᵢ, and Cᵢ in series and connected parallelly to the remining inputs to sub unit (102a). The pull-down sub unit (102b) is complimentary (also mirror) to the pull-up sub unit and both the sub units generate an output Sum (S̅ᵢ̅) for the adder.

In the full adder as disclosed in FIG. 1, the relationship between the inputs and outputs is expressed by logical Boolean expressions (1) and (2). These equations are used in digital systems to compute the addition of two binary inputs Aᵢ, Bᵢ, and carry-in Cᵢ:

$${S}_{i} = {C}_{i} ⊕ {A}_{i} ⊕ {B}_{i} \qquad ( 1 )$$

$${C}_{i + 1} = {A}_{i} {B}_{i} + {C}_{i} ( {A}_{i} + {B}_{i} ) \qquad ( 2 )$$

These expressions define the computation of the sum (Sᵢ) and carry-out (Cᵢ₊₁) of the full adder. Carry propagation becomes the critical path in multi-bit adders, leading to significant delays in the overall calculation. As a result, sum (Sᵢ) computation can tolerate a little computation delay, allowing the carry-out (Cᵢ₊₁) signal to be used for the sum computations. This approach can reduce the transistor count in the circuit. The sum (Sᵢ) in the full adder is evaluated using the expression given by (3).

$${S}_{i} = \overline{{C}_{i + 1}} ( {A}_{i} + {B}_{i} + {C}_{i} ) + {A}_{i} {B}_{i} {C}_{i} \qquad ( 3 )$$

The boolean expression given by egns. (2) & (3) are used for the realization of mirror design full adders (MDFA) as shown in FIG. 1.

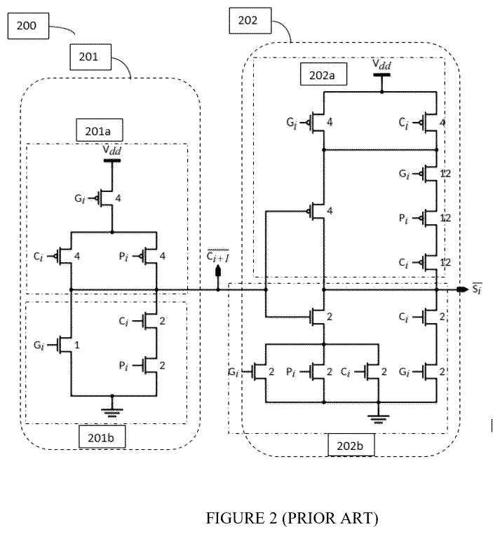

In accordance with another embodiment of the prior art, FIG. 2 illustrates Full Adder using Generate and Propagate (FAGP) which requires 18 transistors, but it is not an optimized design for full adder cell. The circuit comprises a carry-out generating circuit (201) and a sum generating circuit (202). The carry-out generating circuit is configured to generate a first output signal (C̅ᵢ̅₊̅₁̅) based on a first input signal (Gᵢ), a second input signal (Pᵢ) and a third input signal (Cᵢ).

The adder circuit as disclosed in FIG. 2 comprises a plurality of pull-up networks and pull-down networks wherein each pair of pull-up and pull-down network are complimentary in structure.

The carry out generating circuit (201) may comprise sub-units in the form of a first pull up network sub unit (201a) and a first pull-down network sub unit (201b). The pull up sub unit (201a) is configured to receive inputs Cᵢ and Pᵢ in parallel PMOS transistors and an input Gᵢ in a PMOS transistor in series with the input Cᵢ and Pᵢ. The pull-down sub unit (201b) is complimentary to the pull-up sub unit and both the sub units generate an output signal (C̅ᵢ̅₊̅₁̅) which becomes an input for the sum bit generating circuit (202).

The sum bit generating circuit (202) may comprise sub units in the form of a second pull up network sub unit (202a) and a second pull-down network sub unit (202b). The pull up sub unit (202a) is configured to receive inputs Cᵢ, Pᵢ and Gᵢ in series PMOS transistors parallelly placed with a PMOS transistor receiving input signal (C̅ᵢ̅₊̅₁̅). There are two further PMOS transistors for inputs Gᵢ and Cᵢ in parallel and connected in series to the remining inputs to sub unit (202a). The pull-down sub unit (202b) is complimentary to the pull-up sub unit and both the sub units generate an output Sum (S̅ᵢ̅) for the adder.

The FAGP may be realized using 18 transistors per bit and may be achieved through a two-stage computation approach.

The first stage of the adder computes the generate (Gᵢ) and propagate (Pᵢ) terms for each bit, as defined by (4) and (5):

$${G}_{i} = {A}_{i} {B}_{i} \qquad ( 4 )$$

$${P}_{i} = {A}_{i} ⊕ {B}_{i} \qquad ( 5 )$$

Pᵢ is called “carry-propagate” because carry-in propagates to carry-out when Pᵢ is high. When Gᵢ is high, the bits being added produce a carry-out, which is why the variable is known as “carry-generate”. In the second stage, carry-generate (Gᵢ) and carry-propagate (Pᵢ) terms for each bit are then combined to produce the sum (Sᵢ) and carry-out (Cᵢ₊₁) using the expressions given by (6) and (7).

Using the same approach as used for the evaluation of sum (Sᵢ) in (3), the sum (Sᵢ) has been expressed in terms of Gᵢ, Pᵢ, and Cᵢ. The realization of full adders using the Boolean expressions given by (6) and (7), are referred to as Full Adder using Generate and Propagate (FAGP).

$${C}_{i + 1} = {G}_{i} + {C}_{i} {P}_{i} \qquad ( 6 )$$

$${S}_{i} = {P}_{i} ⊕ {C}_{i} = \overline{{C}_{i + 1}} ( {C}_{i} + {G}_{i} + {P}_{i} ) + {G}_{i} {C}_{i} \qquad ( 7 )$$

As discussed earlier, the fundamental reason for the inefficiency of the FAGP design is that the sum is calculated using Gᵢ and Pᵢ, which are redundant boolean variables. A full adder cannot generate carry (Gᵢ) and propagate carry (Pᵢ) at the same time. As the sum (Sᵢ) is expressed in terms of Gᵢ, Pᵢ, and Cᵢ, the mirror property does not hold like equation (3).

The present invention proposes a selective carry propagate full adder (SCPFA) circuit, which aims to increase the speed and efficiency of multi-bit adders. Unlike traditional full adder designs, which are often specific to certain logic styles, the proposed design can be easily integrated into different computing systems, making it adaptable to various logic styles. This flexibility allows for seamless incorporation into diverse digital architectures, enabling efficient binary addition operations across different platforms.

In the forthcoming sections, various implementations of the full adder circuit in different logic styles will be discussed in detail such that their implementations become apparent to those skilled in the art.

Full Adder using Static CMOS Logic:

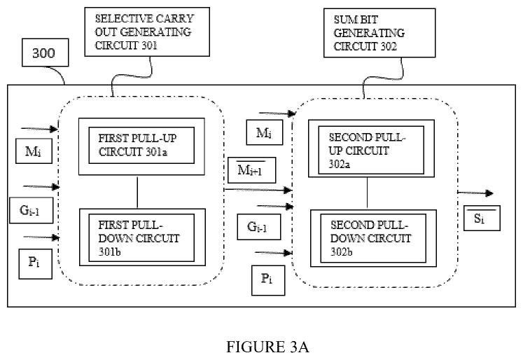

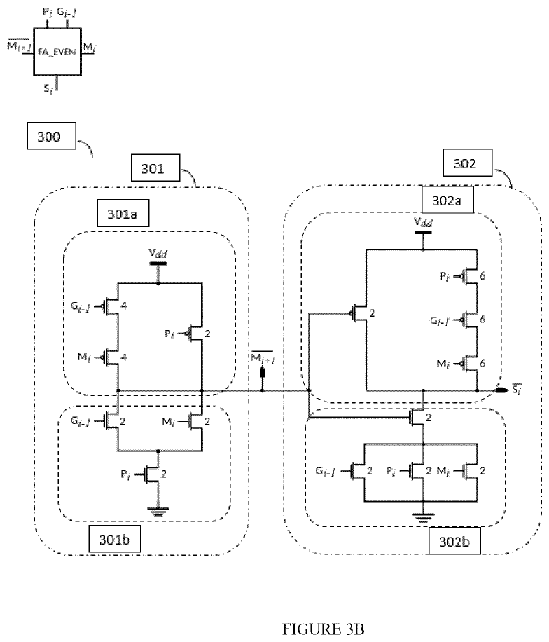

In accordance with one embodiment of the present invention, FIG. 3A illustrates a block diagram for a full adder circuit (300) in static CMOS style. The circuit comprises a plurality of pull-up networks and pull-down networks wherein each pair of pull-up and pull-down network are complimentary in structure. The circuit broadly comprises of two units viz. the selective carry out generating circuit (301) and the sum bit generating circuit (302). The selective carry out generating unit comprises a first pull-up circuit (301a) and a first pull-down circuit (301b), connected to each other and configured to produce a first intermediate output selective carry out bit (M̅ᵢ̅₊̅₁̅). The sum bit generating unit comprises a second pull-up circuit (302a) and a second pull-down circuit (302b) connected to each other and configured to receive the intermediate output (M̅ᵢ̅₊̅₁̅) from the selective carry out generating circuit as one of the inputs and producing a sum (S̅ᵢ̅) as the output.

In accordance with another embodiment of the present invention, FIG. 3B illustrates a schematic diagram illustrating the high-speed carry propagate adder as seen in FIG. 3A. The circuit as presented in FIG. 3A may be divided into two sub-circuits viz. the selective carry out generating circuit (301) and the sum bit generating circuit (302). There are two power source terminals V₁ and V₂ across which is applied an operation voltage (V_{dd}). The selective carry out generating circuit is configured to receive a first input signal (Pᵢ), a second input signal (Gᵢ₋₁) and a third input signal (Mᵢ) and generate a first output signal (M̅ᵢ̅₊̅₁̅). The selective carry out generating circuit is subdivided into a first pull up and a first pull-down network pair wherein first pull-down network comprises two NMOS transistors in parallel configured to receive a selective carry in (M₁) and a generate from the previous adder stage (Gᵢ₊₁) and an NMOS transistor connected in series to the two transistors configured to receive a propagate signal (Pᵢ) and a ground voltage supply. The first pull up network is a complimentary logic of the first pull down network and comprises two PMOS transistors in series and a PMOS transistor in parallel to the two transistors positioned between the first power source terminal V₁ and the first output signal (M̅ᵢ̅₊̅₁̅).

The sum bit generating circuit is coupled to the selective carry out generating circuit and configured to receive the output signal (M̅ᵢ̅₊̅₁̅) from the selective carry out generating circuit, the first input signal (Pᵢ), the second input signal (Gᵢ₋₁) and the third input signal (Mᵢ) and generate a second output signal (S̅ᵢ̅). The sum bit generating circuit is subdivided into a second pull up and second pull down network pair wherein the second pull down network comprises three NMOS transistors in parallel configured to receive a selective carry in (Mᵢ), a generate from the previous adder stage (Gᵢ₋₁) and a propagate signal (Pᵢ), and an NMOS transistor connected in series to the three transistors configured to receive the selective carry out signal (M̅ᵢ̅₊̅₁̅) from the selective carry generating circuit and a ground voltage supply. The second pull up network is a complimentary logic of the second pull down network and comprises three PMOS transistors in series and a PMOS transistor in parallel to the three transistors positioned between the second power source terminal V₂ and the second output signal (S̅ᵢ̅).

Carry propagation forms the critical path in multi-bit adders which limits the speed of operation. As given by equation (6) in the foregoing section, the traditional full adder cell either generates a carry (Gᵢ) or propagates the input carry (CᵢPᵢ) to the next stage. Equation (6) has been reproduced herein for reference:

$${C}_{i + 1} = {G}_{i} + {C}_{i} {P}_{i} = Carry Generate + Carry Propagate \qquad ( 6 )$$

Instead of propagating carry-out (Cᵢ₊₁) and using it for sum computation, it is proposed herein to selectively propagating only Carry-Propagate (CᵢPᵢ) bits in the critical path and using it for the sum computation.

For the purposes, a variable ‘M’ is defined which denotes Carry Propagate (CᵢPᵢ), such that:

$${M}_{i + 1} = {C}_{i} {P}_{i} \qquad ( 8 )$$

Then using equation (6) and (8), we can derive:

$${C}_{i + 1} = {G}_{i} + {C}_{i} {P}_{i} = {G}_{i} + {M}_{i + 1} \qquad ( 9 )$$

Similarly, we can derive the Carry as:

$${C}_{i} = {G}_{i - 1} + {M}_{i} \qquad ( 10 )$$

Now using equation (8) and (10), we can derive:

$${M}_{i + 1} = {C}_{i} {P}_{i} = ( {G}_{i - 1} + {M}_{i} ) {P}_{i} \qquad ( 11 )$$

Again, we can express the sum as:

$${S}_{i} = {C}_{i} ⊕ {A}_{i} ⊕ {B}_{i} = {C}_{i} ⊕ {P}_{i} = ( \overline{{C}_{i} {P}_{i}} ) ( {C}_{i} + {P}_{i} )$$

Using equations (8) and (10), we get:

$${S}_{i} = \overline{{M}_{i + 1}} ( {G}_{i - 1} + {M}_{i} + {P}_{i} ) \qquad ( 12 )$$

The realization of full adders using the boolean expressions given by equations (11) and (12) require 14 transistors in static CMOS implementation, as shown in FIGS. 3A and 3B. The full adder design employs fewer transistors of comparable size, resulting in a higher operating speed due to fewer parasitic resistors and capacitors. The number of transistors used in the proposed design are reduced by computing the sum using independent boolean variables Gᵢ₋₁ and Pᵢ.

Thus, instead of propagating carry-out (Cᵢ₊₁) and using it for sum computation, selectively propagating only Carry-Propagate (CᵢPᵢ) bits in the critical path and using it for the sum computation have enabled in reduction of the number of transistors being used in implementing the logic and increased efficiency in sum computation.

Logical Effort is a widely used approach for calculating the delays of digital logic circuits. Logical Effort measures the relative ability of a gate to supply current for a fixed input capacitance, hence the smaller the logical effort, the faster the circuit. The logical effort of carry signal will be an appropriate performance metric for comparison of different full adder designs. Table I shows the performance comparison of different full adder designs using logical effort. Although the FAGP circuit uses fewer transistors than the MDFA, the logical effort is 18.55% higher due to the large PMOS stack. The proposed SCPFA adder design uses only 14 transistors and exhibits a 33.33% reduction in logical effort compared to the MDFA.

TABLE I
PERFORMANCE COMPARISON USING LOGICAL EFFORT

| | | Logical Effect for Carry Signal | |
|---|---|---|---|
| Pull Adder Design | No. of Transistor required in FA | $g = \frac{\text{?}}{\text{?}}$ | Improvement [symbol] Mirror Adder |
| Minor Design Fall Adder (MDPA) | 24 | $\frac{( 4 + 2 + 4 + 2 + 6 + 3 ) + ( \text{?} + 2 )}{( 2 + 1 )} = 9$ | — |
| Full Adder using G and P (BAGP) | 18 | $\frac{( 4 + 2 + 4 + 2 + 12 + 2 ) + ( \text{?} + \text{?} )}{( 2 + 1 )} = 10.67$ | −18.55% |
| Selective Carry Propagate Fall Adder (SCPBA) | 14 | $\frac{( 4 + 2 + \text{?} + \text{?} ) + ( \text{?} + 2 )}{( 2 + 1 )} = 6$ | +33.33% |

[symbol]

indicates data missing or illegible when filed

Trade-offs between delay and other features, such as area and energy dissipation, are available with different digital logic styles. The advantage of the static CMOS style is its robustness against voltage scaling and transistor sizing, achieved through a ratio less circuit, which enables reliable operation at low voltage. Dynamic CMOS circuits can operate at higher speeds since they contain fewer transistors, but they often have higher power consumption overall, including the power needed by the clock tree. Since fewer transistors are required, pseudo-NMOS, transmission gate, and pass transistor logic often offer area savings. There are advantages and disadvantages to each logic design style, but they provide choices depending on the constraints and requirements.

The proposed selective carry propagate full adder method may be implemented with but not limited to other logic designs such as dynamic CMOS logic, pseudo-NMOS, transmission gate, pass transistor logic, etc. The optimization at the architecture level, such as carry skip, carry save, etc., also applies to the proposed design.

Some proposed applications of the full adder design are provided herein. The proposed SCPFA cell shown in FIGS. 3A and 3B generates an inverted Sum and Mₒᵤₜ. Thus, in a multi-bit adder design, an inverter is required to be added at the output of the full adder. As the inverter comes into the critical path, it needs to be eliminated for faster speed.

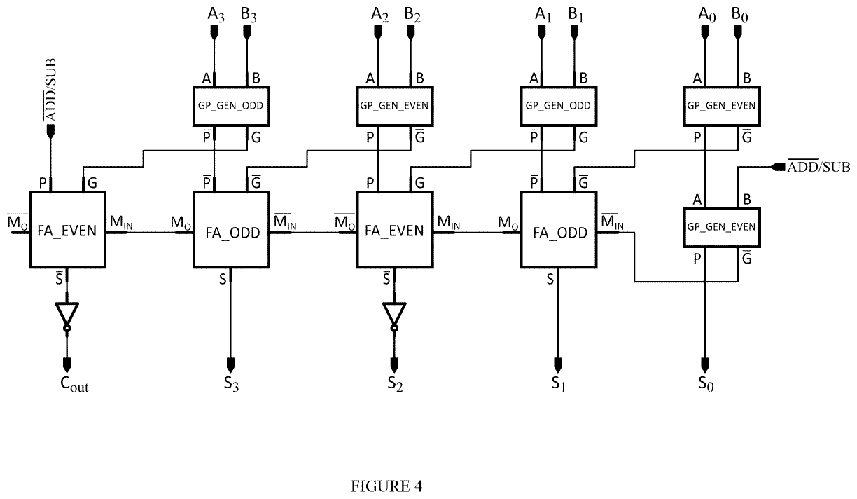

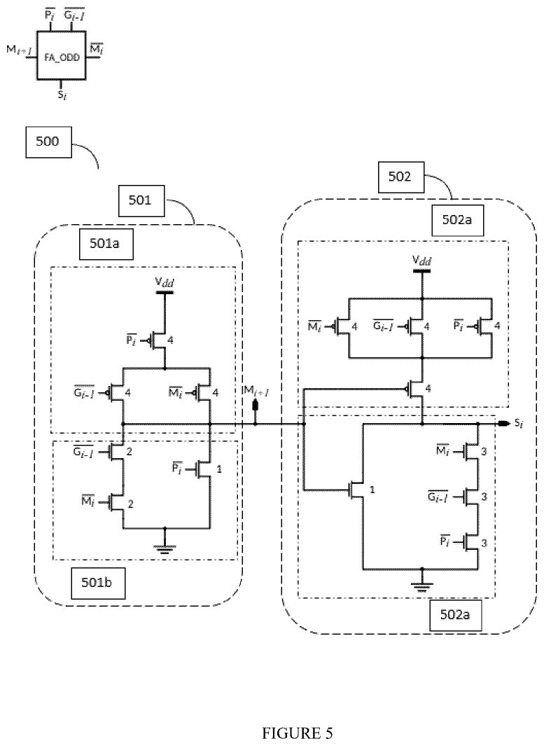

In accordance with yet another embodiment of the present invention, FIG. 4 illustrates a Multi-bit Selective Carry Propagate Adder and Subtractor using SCPFA cell wherein the requirement of the inverter in the critical path has been eliminated by cascading a full adder block (named as FA_EVEN with circuit diagram shown in FIG. 3B) output with an inverted full adder block (named as FA_ODD with circuit diagram shown in FIG. 5). The GP_GEN_ODD block will generate P̅ᵢ̅ and Gᵢ, while the GP_GEN_EVEN block will generate Pᵢ and G̅ᵢ̅, where P and G represent propagate and generate respectively, as defined by equations (4) and (5).

Although a 4-bit adder/subtractor design has been shown, it can be extended to any number of bits. Subtraction is achieved using the 2's complement method, where the 2's complement of the subtrahend is added to the minuend, thereby enabling the use of the same hardware for both addition and subtraction. To subtract one number from another, the 2's complement method involves inverting all the bits of the subtrahend and then adding 1 (using the signal A̅D̅D̅/SUB) to the LSB.

The multi-bit design proposed by us can also be implemented with other logic designs such as dynamic logic, pseudo-NMOS, transmission gate, pass transistor, etc, utilizing the Selective Carry Propagate Adder method as given in the boolean expressions given by equations (11) and (12).

In accordance with yet another embodiment of the present invention, FIG. 5 illustrates an inverted selective carry propagate full adder circuit (500). The circuit may be divided into two sub-circuits viz. the selective carry out generating circuit (501) and the sum bit generating circuit (502). There are two power source terminals V₁ and V₂ across which is applied an operation voltage. The selective carry out generating circuit (501) is configured to receive a first input signal (P̅ᵢ̅), a second input signal (G̅ᵢ̅₋̅₁̅) and a third input signal (M̅ᵢ̅) and generate a first output signal (Mᵢ₊₁). The selective carry out generating circuit (501) is subdivided into a first pull up (501a) and a first pull-down network (501b) pair wherein first pull-down network comprises two NMOS transistors in series configured to receive a selective carry in (M̅ᵢ̅) and a generate carry from the previous adder stage (G̅ᵢ̅₋̅₁̅) and an NMOS transistor connected in parallel to the two transistors configured to receive a propagate signal (P̅ᵢ̅) and a ground voltage supply. The first pull up network (501a) is a complimentary logic of the first pull down network and comprises two PMOS transistors in parallel and a PMOS transistor in series to the two transistors positioned between the first power source terminal V₁ and the first output signal (Mᵢ₊₁).

The sum bit generating circuit (502) is coupled to the selective carry out generating circuit (501) and configured to receive the output signal (Mᵢ₊₁) from the selective carry out generating circuit, the first input signal (P̅ᵢ̅), the second input signal (G̅ᵢ̅₋̅₁̅) and the third input signal (M̅ᵢ̅) and generate a second output signal (Sᵢ). The sum bit generating circuit is subdivided into a second pull up (502a) and second pull down network (502b) pair wherein the second pull down network comprises three NMOS transistors in series configured to receive a selective carry in (M̅ᵢ̅), a generate carry from the previous adder stage (G̅ᵢ̅₋̅₁̅) and a propagate signal (P̅ᵢ̅), and an NMOS transistor connected in parallel to the three transistors configured to receive the selective carry out signal (Mᵢ₊₁) from the selective carry generating circuit and a ground voltage supply. The second pull up network is a complimentary logic of the second pull down network and comprises three PMOS transistors in parallel and a PMOS transistor in series to the three transistors positioned between the second power source terminal V₂ and the second output signal (Sᵢ).

Full Adder using Transmission Gate and Pass Transistor Logic:

The transmission gate and pass transistor logic design as will be disclosed in the forthcoming section is complex and can result in multiple designs for the same logic generation. The transmission gates and pass transistor logic style result in signal degradation and make the logic circuit more sensitive to noise, which can affect its accuracy and reliability.

The logic circuit can be implemented in a variety of transmission gate and pass transistor logic style.

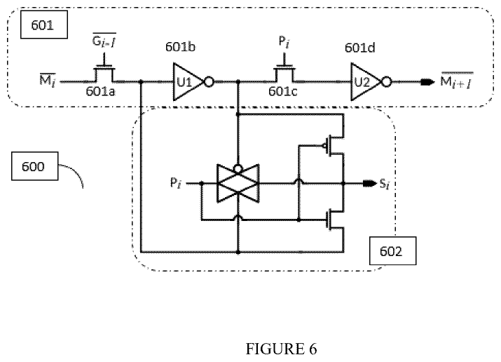

In accordance with another embodiment of the present invention, FIG. 6 illustrates a full adder (600) using transmission gate and pass transistor logic using 10 transistors. The circuit as disclosed comprises a selective carry out generator circuit (601) and a sum generator circuit (602) wherein the carry out generator circuit comprises a selective carry input (M̅ᵢ̅) which passes through a first NMOS transistor (601a) with a generate carry input (G̅ᵢ̅₋̅₁̅) from the previous adder stage and generates a first non-inverted output in which a NOT operation is performed to generate a second inverted output. The second output then passes through a second NMOS transistor (601b) with a propagate input (Pᵢ) and generates a third output in which a NOT operation is performed to derive a selective carry output (M̅ᵢ̅₊̅₁̅). The sum generator circuit (602) comprises three inputs comprising providing a propagate signal input (Pᵢ), the first output from the selective carry out generator circuit and the second output from the selective carry out generator circuit into an inverter and transmission gate to generate a sum (Sᵢ).

In order to design the full adder cell in the transmission gate and pass transistor logic style, modified boolean expressions have been used as given by equations (13) and (14).

Using eqn. (11) and (12), we get:

$$\overline{{M}_{i + 1}} = \overline{{P}_{i}} + \overline{{G}_{i - 1}} \cdot \overline{{M}_{i}} = \overline{( {G}_{i - 1} + {M}_{i} ) {P}_{i}} \qquad ( 13 )$$

$${S}_{i} = \overline{{M}_{i + 1}} ( {G}_{i - 1} + {M}_{i} + {P}_{i} ) = ( {G}_{i - 1} + {M}_{i} ) ⊕ {P}_{i} \qquad ( 14 )$$

Full Adder using Pass Transistor Logic:

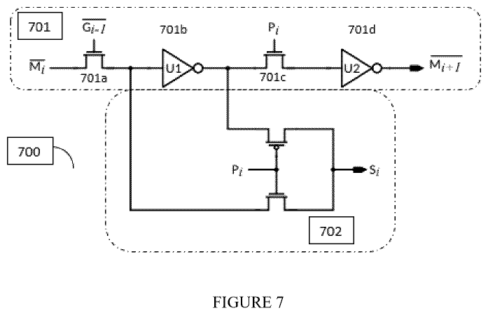

In accordance with yet another embodiment of the present invention, FIG. 7 illustrates a full adder (700) using Pass Transistor Logic that uses solely pass transistor logic and requires only 8 transistors. The circuit as disclosed comprises a selective carry out generator circuit (701) and a sum generator circuit (702) wherein the carry out generator circuit comprises a selective carry input (M̅ᵢ̅) which passes through a first NMOS transistor (701a) with a generate carry input (G̅ᵢ̅₋̅₁̅) from the previous adder stage and generates a first non-inverted output in which a NOT operation is performed to generate a second inverted output. The second output then passes though a second NMOS transistor (701c) with a propagate input (Pᵢ) and generates a third output in which a NOT operation is performed to derive a selective carry output (M̅ᵢ̅₊̅₁̅). The sum generator circuit comprises three inputs comprising providing a propagate signal input (Pᵢ) at the gate of a NMOS and PMOS pass transistor, the first non-inverted output and the second inverted output into the pass transistor to generate a sum (Sᵢ).

In order to design the full adder cell in the transmission gate and pass transistor logic style, modified boolean expressions have been used as given by (13) and (14).

Using eqn. (11) and (12), we get:

$$\overline{{M}_{i + 1}} = \overline{{P}_{i}} + \overline{{G}_{i - 1}} \cdot \overline{{M}_{i}} = \overline{( {G}_{i - 1} + {M}_{i} ) {P}_{i}} \qquad ( 13 )$$

$${S}_{i} = \overline{{M}_{i + 1}} ( {G}_{i - 1} + {M}_{i} + {P}_{i} ) = ( {G}_{i - 1} + {M}_{i} ) ⊕ {P}_{i} \qquad ( 14 )$$

One key advantage of this design (FIG. 6 and FIG. 7) is that multi-bit addition can be achieved simply by cascading the full-adder cell, eliminating the requirement for inversion steps. The main problem with the transmission gates and pass transistor logic design is threshold voltage loss, which can hinder the multi-bit adder from functioning properly due to voltage drop. In the proposed transmission gate and pass transistor logic design, the output threshold voltage loss is mitigated by using an output inverter in the critical path as a voltage level-restoring circuit. The inverter in the critical path makes sure that the input and output are appropriately isolated while also providing the necessary drive strength for the next stage.

### Selective Carry Look Ahead Adder:

The Carry Look Ahead Adder (CLA) computes the carry-in for each bit directly from the inputs, employing lookahead carry logic. Compared to conventional ripple carry adders, CLA necessitates a larger number of components to implement a stage of a multi-bit adder.

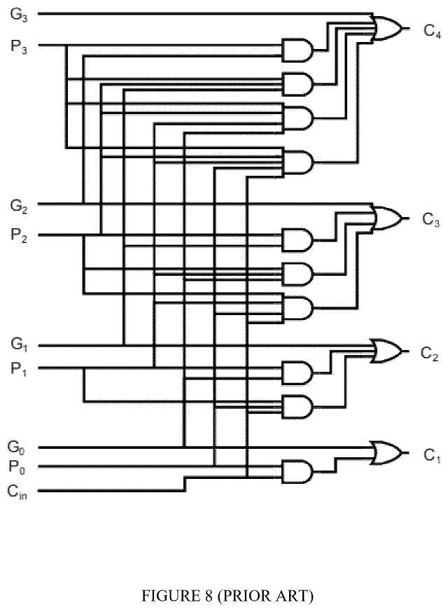

In accordance with an embodiment of the prior art, FIG. 8 illustrates a traditional carry look ahead adder wherein it can be seen that the number of stages of computation is increased thereby increasing the components required in the circuit. A Carry Look Ahead Adder circuit will have a substantially shorter delay than a traditional ripple carry adder circuit. However, as the number of stages increases, the number of components increases even more dramatically, resulting in a maximum 4-bit block CLA architecture.

Two 4-bits binary numbers A and B need to be added, and they are represented as A₃A₂A₁A₀ and B₃B₂B₁B₀ respectively where the external carry-in is denoted as C₀. Then the sum of this addition, S₃S₂S₁S₀ can be calculated by full adders. Thus, S₃S₂S₁S₀=A₃A₂A₁A₀⊕B₃B₂B₁B₀⊕C₃C₂C₁C₀, where C₃, C₂, and C₁ are the carry-outs of previous bits. The carry look ahead adder circuit is shown in FIG. 8, where using the input P₁ and Gᵢ, the output carry-out bits C₄, C₃, C₂, and C₁ are estimated directly and do not depend upon previous carry values.

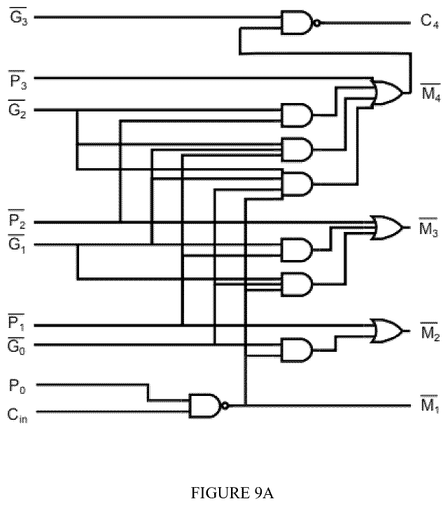

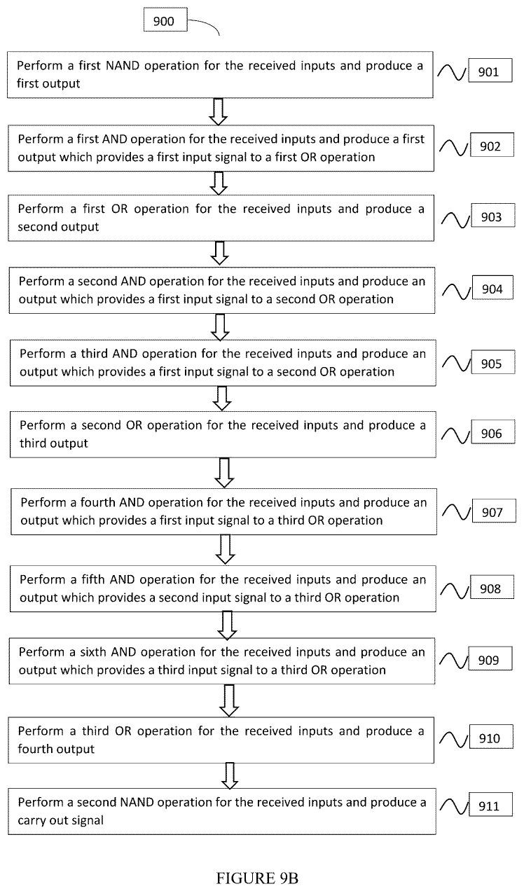

In accordance with another embodiment of the present invention, FIG. 9A illustrates a selective carry look ahead adder circuit. The circuit comprises first and second NAND gates, first, second, third, fourth, fifth and sixth AND gates, first, second and third OR gates. The first NAND gate has first and second input terminals adapted to receive a first Carry in (C₀) and a first propagate (P₀) and produces a first output as inverted selective carry in signal (M̅₁̅). The first AND gate first and second input terminals adapted to receive the first output inverted selective carry in (M̅₁̅) and a first inverted generate carry (G̅₀̅) and produce an output which provides a first input signal to a first OR gate. The first OR gate has first and second input terminals adapted to receive an output from the first AND gate and an inverted second propagate (P̅₁̅) to produce a second output as inverted selective carry in signal (M̅₂̅). The second AND gate has first, second and third input terminals adapted to receive the first output inverted selective carry in (M̅₁̅), the inverted first generate carry (G̅₀̅) and an inverted second generate carry (G̅₁̅) and produce an output which provides a first input signal to a second OR gate. The third AND gate has first and second input terminals adapted to receive the inverted second propagate (P̅₁̅) and inverted second generate carry (G̅₁̅) and produce an output which provides a second input signal to a second OR gate. The second OR gate has first, second and third input terminals adapted to receive an output from the second AND gate, output from the third AND gate and an inverted third propagate (P̅₂̅) and produce a third output as inverted selective carry in signal (M̅₃̅). The fourth AND gate has first, second, third and fourth input terminals adapted to receive the output (M̅₁̅) from the first NAND gate, the inverted first generate carry (G̅₀̅), the inverted second generate carry (G̅₁̅) and an inverted third generate carry (G̅₂̅) to produce an output which provides a first input signal to a third OR gate. The fifth AND gate has first, second and third input terminals adapted to receive the inverted second propagate (P̅₁̅), the inverted second generate carry (G̅₁̅) and an inverted third generate carry (G̅₂̅) to produce an output which provides a second input signal to a third OR gate. The sixth AND gate has first and second input terminals adapted to receive the third inverted propagate (P̅₂̅) and the inverted third generate carry (G̅₂̅) to produce an output which provides a third input signal to a third OR gate. The third OR gate has first, second, third and fourth input terminals adapted to receive an output from the fourth AND gate, output from the fifth AND gate, output from the sixth AND gate and a fourth inverted propagate (P̅₃̅) and produce a fourth output as inverted selective carry in signal (M̅₄̅). The second NAND gate has first and second input terminals adapted to receive output from the third OR gate and a fourth inverted generate carry signal (G̅₃̅) and produce a carry out signal (C̅₄̅).

In accordance with another embodiment of the present invention, FIG. 9B illustrates method of generating a sum using selective carry look ahead adder circuit

At step 901, the system performs a first NAND operation for first and second input terminals adapted to receive a first Carry in (C₀) and a first propagate (P₀) and produces a first output as inverted selective carry in signal (M₁).

At step 902, the system performs a first AND operation for first and second input terminals adapted to receive the first output inverted selective carry in (M₁) and a first inverted generate carry (G₀) and produces an output which provides a first input signal to a first OR operation.

At step 903, the system performs a first OR operation for first and second input terminals adapted to receive an output from the first AND operation and an inverted second propagate (P₁) to produces a second output as inverted selective carry in signal (M₂).

At step 904, the system performs a second AND operation for first, second and third input terminals adapted to receive the first output inverted selective carry in (M₁), the inverted first generate carry (G₀) and an inverted second generate carry (G₁) and produces an output which provides a first input signal to a second OR operation.

At step 905, the system performs a third AND operation for first and second input terminals adapted to receive the inverted second propagate (P₁) and inverted second generate carry (G₁) and produces an output which provides a second input signal to a second OR operation.

At step 906, the system performs a second OR operation for first, second and third input terminals adapted to receive an output from the second AND operation, output from the third AND operation and an inverted third propagate (P₂) and produces a third output as inverted selective carry in signal (M₃).

At step 907, the system performs a fourth AND operation for first, second, third and fourth input terminals adapted to receive the output (M₁) from the first NAND operation, the inverted first generate carry (G₀), the inverted second generate carry (G₁) and an inverted third generate carry (G₂) to produces an output which provides a first input signal to a third OR operation.

At step 908, the system performs a fifth AND operation for first, second and third input terminals adapted to receive the inverted second propagate (P₁), the inverted second generate carry (G₁) and an inverted third generate carry (G₂) to produces an output which provides a second input signal to a third OR operation.

At step 909, the system performs a sixth AND operation for first and second input terminals adapted to receive the third inverted propagate (P₂) and the inverted third generate carry (G₂) to produces an output which provides a third input signal to a third OR operation.

At step 910, the system performs a third OR operation for first, second, third and fourth input terminals adapted to receive an output from the fourth AND operation, output from the fifth AND operation, output from the sixth AND operation and a fourth inverted propagate (P₃) and produces a fourth output as inverted selective carry in signal (M₄).

At step 911, the system performs a second NAND operation for first and second input terminals adapted to receive output from the third OR operation and a fourth inverted generate carry signal (G₃) and produces a carry out signal (C₄).

Using the equation (13), the expression used for the estimation of selective carry Mᵢ is as mentioned below:

$$\overline{{M}_{1}} = \overline{{P}_{0} {C}_{ι n}} \qquad ( 15 )$$

$$\overline{{M}_{2}} = \overline{{P}_{1}} + \overline{{G}_{0}} \cdot \overline{{M}_{1}} \qquad ( 16 )$$

$$\overline{{M}_{3}} = \overline{{P}_{2}} + \overline{{G}_{1}} \cdot \overline{{P}_{1}} + \overline{{G}_{1}} \cdot \overline{{G}_{0}} \cdot \overline{{M}_{1}} \qquad ( 17 )$$

$$\overline{{M}_{4}} = \overline{{P}_{3}} + \overline{{G}_{2}} \cdot \overline{{P}_{2}} + \overline{{G}_{2}} \cdot \overline{{G}_{1}} \cdot \overline{{P}_{1}} + \overline{{G}_{2}} \cdot \overline{{G}_{1}} \cdot \overline{{G}_{0}} \cdot \overline{{M}_{1}} \qquad ( 18 )$$

The equation (18) also confirms that the generation of selective carry out M̅₄̅ requires much lesser transistor count compared to C₄ generation in a traditional CLA circuit. The sum can be calculated using equation (12), which further results in a significant reduction in the transistor count compared to the traditional CLA circuit. Thus, with the above two-way reduction of transistors, our proposed selective carry look ahead adder significantly reduces the hardware required for the parallel binary adder.

Various embodiments of the present invention highlight the potential of the proposed selective carry propagate full adder circuit to overcome the limitations of traditional full adder designs. The significant reduction in propagation delay, energy consumption, and transistor count demonstrates the effectiveness of the selective carry propagate adder approach. The improved performance of the proposed circuit has implications for various digital systems, and it can enhance the speed and efficiency of microprocessors, digital signal processors, and multiplier accumulator units (MAC). The reduced energy consumption also makes the circuit suitable for energy-efficient computing systems, contributing to sustainability and reduced operational costs. Furthermore, efficient transistor utilization and reduced chip area requirements enable more compact and cost-effective integrated circuit designs.

The terms “or” and “and/or” as used herein are to be interpreted as inclusive or meaning any one or any combination. Therefore, “A, B or C” or “A, B and/or C” may mean “any of the following: A; B; C; A and B; A and C; B and C; A, B and C.” An exception to this definition will occur only when a combination of elements, functions, steps or acts are in some way inherently mutually exclusive.

Any combination of the above features and functionalities may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set as claimed in claims that issue from this application, in the specific form in which such claims issue, including any subsequent correction.

1. A selective carry propagate full adder circuit (300) in static CMOS logic, comprising:
first (V₁) and second (V₂) power source terminals across which is applied an operation voltage;
a selective carry out generating circuit configured to receive a first input signal (Mᵢ), a second input signal (Pᵢ) and a third input signal (Gᵢ₋₁) and generate a first output signal (M̅ᵢ̅₊̅₁̅); and
a sum bit generating circuit, coupled to the selective carry out generating circuit, configured to receive the output signal (M̅ᵢ̅₊̅₁̅) from the selective carry out generating circuit, the first input signal (Mᵢ), the second input signal (Pᵢ) and the third input signal (Gᵢ₋₁) and generate a second output signal (S̅ᵢ̅);
wherein the selective carry out generating circuit comprises a first pull up network and a first pull down network,
wherein the first pull down network comprises two NMOS transistors in parallel configured to receive a selective carry in (Mᵢ) and a generate from the previous adder stage (Gᵢ₋₁) and an NMOS transistor connected in series to the two transistors configured to receive a propagate signal (Pᵢ) and a ground voltage supply,
wherein the first pull up network is a complimentary logic of the first pull down network,
wherein the first output signal generated is a selective carry out signal (M̅ᵢ̅₊̅₁̅),
wherein the sum bit generating circuit comprises a second pull up network and a second pull down network,
wherein the second pull down network comprises three NMOS transistors in parallel configured to receive a selective carry in (Mᵢ), a generate carry from the previous adder stage (Gᵢ₋₁) and a propagate signal (Pᵢ), and an NMOS transistor connected in series to the three transistors configured to receive the selective carry out signal (M̅ᵢ̅₊̅₁̅) from the selective carry generating circuit and a ground voltage supply,
wherein the second pull up network is a complimentary logic of the second pull down network, and
wherein the second output signal generated is a sum (S̅ᵢ̅) of the inputs.

2. The selective carry propagate full adder circuit as claimed in claim 1, wherein the first pull up network comprises two PMOS transistors in series and a PMOS transistor in parallel to the two transistors positioned between the first power source terminal V₁ and the first output signal.

3. The selective carry propagate full adder circuit as claimed in claim 1, wherein the second pull up network comprises three PMOS transistors in series and a PMOS transistor in parallel to the three transistors positioned between the second power source terminal V₂ and the second output signal.

4. A selective carry propagate full adder circuit (600) in transmission gate logic, comprising:
a selective carry out generator circuit; and
a sum generator circuit;
wherein the carry out generator circuit comprises:
a selective carry input (M̅ᵢ̅) which passes through a first NMOS transistor with a generate carry input from the previous adder stage (G̅ᵢ̅₋̅₁̅) and generates a first output,
the first output passes through a first NOT gate and generates a second output,
the second output passes through a second NMOS transistor with a propagate input (Pᵢ) and generates a third output,
the third output passes through a second NOT gate to provide a selective carry output (M̅ᵢ̅₊̅₁̅), and
wherein the sum generator circuit comprises three inputs comprising providing a propagate signal input (Pᵢ), the first output from the selective carry out generator circuit and the second output from the selective carry out generator circuit into an inverter and transmission gate to generate a sum (Sᵢ).

5. A selective carry propagate full adder circuit in pass transistor logic, comprising:
a selective carry out generator circuit; and
a sum generator circuit;
wherein the selective carry out generator circuit comprises:
a selective carry input (M̅ᵢ̅) which passes through a first NMOS transistor with a generate carry input from the previous adder stage (G̅ᵢ̅₋̅₁̅) and generates a first non-inverted output,
the first output passes through a first NOT gate and generates a second inverted output,
the second output passes through a second NMOS transistor with a propagate input (Pᵢ) and generates a third output,
the third output passes through a second NOT gate to provide a selective carry output (M̅ᵢ̅₊̅₁̅), and
wherein the sum generator circuit comprises three inputs comprising providing a propagate signal input (Pᵢ), the first non-inverted output and the second inverted output into a NMOS and PMOS pass transistor to generate a sum (Sᵢ).

6. A method of adding three bits using a selective carry look ahead full adder circuit comprising:
performing a first NAND operation for first and second input terminals adapted to receive a first Carry in (C₀) and a first propagate (P₀) and producing a first output as inverted selective carry in signal (M̅₁̅);
performing a first AND operation for first and second input terminals adapted to receive the first output inverted selective carry in (M̅₁̅) and a first inverted generate carry (G̅₀̅) and produce an output which provides a first input signal to a first OR operation;
performing a first OR operation for first and second input terminals adapted to receive an output from the first AND operation and an inverted second propagate (P̅₁̅) to produce a second output as inverted selective carry in signal (M̅₂̅);
performing a second AND operation for first, second and third input terminals adapted to receive the first output inverted selective carry in (M̅₁̅), the inverted first generate carry (G̅₀̅) and an inverted second generate carry (G̅₁̅) and produce an output which provides a first input signal to a second OR operation;
performing third AND operation for first and second input terminals adapted to receive the inverted second propagate (P̅₁̅) and inverted second generate carry (G̅₁̅) and produce an output which provides a second input signal to a second OR operation;
performing a second OR operation for first, second and third input terminals adapted to receive an output from the second AND operation, output from the third AND operation and an inverted third propagate (P̅₂̅) and produce a third output as inverted selective carry in signal (M̅₃̅);
performing a fourth AND operation for first, second, third and fourth input terminals adapted to receive the output (M̅₁̅) from the first NAND operation, the inverted first generate carry (G̅₀̅), the inverted second generate carry (G̅₁̅) and an inverted third generate carry (G̅₂̅) to produce an output which provides a first input signal to a third OR operation;
performing a fifth AND operation for first, second and third input terminals adapted to receive the inverted second propagate (P̅₁̅), the inverted second generate carry (G̅₁̅) and an inverted third generate carry (G̅₂̅) to produce an output which provides a second input signal to a third OR operation;
performing a sixth AND operation for first and second input terminals adapted to receive the third inverted propagate (P̅₂̅) and the inverted third generate carry (G̅₂̅) to produce an output which provides a third input signal to a third OR operation;
performing a third OR operation for first, second, third and fourth input terminals adapted to receive an output from the fourth AND operation, output from the fifth AND operation, output from the sixth AND operation and a fourth inverted propagate (P̅₃̅) and produce a fourth output as inverted selective carry in signal (M̅₄̅); and
performing a second NAND operation for first and second input terminals adapted to receive output from the third OR operation and a fourth inverted generate carry signal (G̅₃̅) and produce a carry out signal (C₄).
